(19) United States
(12) Patent Application Publication
(10) Pub. No.: US 2011/0043293 A1
(43) Pub. Date: Feb. 24, 2011

(54) DeMOS VCO

(76) Inventors: Gerhard KNOBLINGER, Villach (AT); Marc TIEBOUT, Finkenstein (AT); Franz KUTTNER, St. Ulrich (AT)

Correspondence Address: SpryIP, LLC IFX, 5009 163rd PL SE, Bellevue, WA, 98006, US

(21) Appl. No.: 12/543,629

(22) Filed: Aug. 19, 2009

(51) Int. Cl. H03B 5/12

(52) U.S. Cl. 331/117 FE

(57) ABSTRACT

The present disclosure relates voltage controlled oscillators (VCO) and digitally controlled oscillators (DCO). In one implementation, a VCO is implemented with drain extended MOS transistors (DeMOS). In another implementation, a DCO is implemented with DeMOS devices.

### RELATED APPLICATIONS

This Application is related to the U.S. Patent Application entitled “DeMOS DCO”, which was filed on even-date with this Application.

### BACKGROUND

Voltage controlled oscillators (VCO) and Digitally controlled oscillators (DCO) are used in a variety of electronic circuits. One particularly important application using VCOs and DCOs is in mobile communications, where VCOs and DCOs are used in a phase-locked loop (PLL) system to generate a frequency with the desired precision and stability characteristic. VCOs and DCOs are also used in a variety of other applications (e.g., radar systems or clock sources for ADC).

Typical analog PLLs include a phase detector that compares the phase relationship of the reference clock to an internal clock, a charge pump and loop filter for setting an analog voltage corresponding to this phase relationship, and a VCO for generating an output clock signal in response to the analog voltage from the charge pump and loop filter. Digital PLLs include substantially the same functional elements as analog PLLs, but those elements are implemented using digital techniques. Therefore, in digital implementations of PLLs, the VCO is replaced with a DCO.

### BRIEF DESCRIPTION OF THE DRAWINGS

The detailed description is described with reference to the accompanying figures. In the figures, the left-most digit(s) of a reference number identifies the figure in which the reference number first appears. The use of the same reference number in different instances in the description and the figures may indicate similar or identical items.

FIG. 1 is a diagram of a voltage controlled oscillator (VCO) according to a first circuit arrangement implementation.

FIG. 2 is a diagram of a VCO 200 according to a second circuit arrangement implementation.

FIG. 3 is a diagram of a digitally controlled oscillator (DCO) according to a third circuit arrangement implementation.

### DETAILED DESCRIPTION

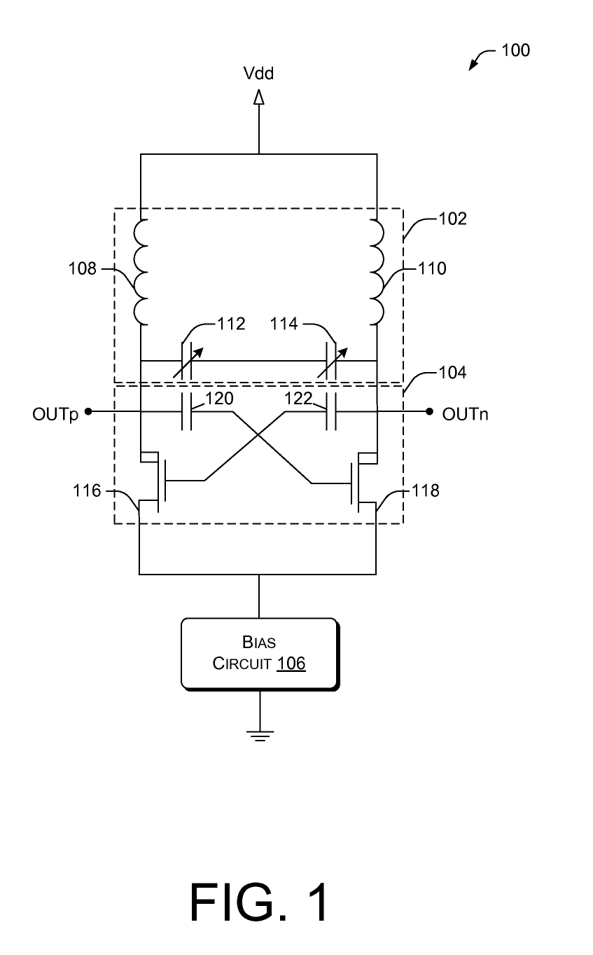

FIG. 1 is a diagram of a differential voltage controlled oscillator (VCO) 100 according to a first circuit arrangement implementation. The VCO 100 includes, but is not limited to, an LC-tank circuit 102, a cross-coupled pair circuit 104, and bias circuit 106.

The LC-tank circuit 102 is coupled to the supply voltage Vdd. The LC-tank circuit 102 includes inductors 108 and 110 and variable capacitors (varactors) 112 and 114, which are respectively used for providing an inductance and a capacitance to generate a differential oscillating signal between output terminals OUTn and OUTp. The inductors 108 and 110 are coupled to Vdd in parallel. varactors 112 and 114 may typically be implemented using diodes or MOS capacitors to implement the tunable tank capacitance. This is achieved by replacing the illustrated variable capacitors 112 and 114 with junction diodes or any MOS transistor used as a variable capacitance by short-circuiting the drain and source.

The cross-coupled pair circuit 104 includes cross-coupled drain extended MOS transistors (DeMOS) 116 and 118. The DeMOS transistors 116 and 118 are cross-coupled such that the gate of the DeMOS transistor 116 is coupled to the drain of the DeMOS transistor 118, and the gate of the DeMOS transistor 118 is coupled to the drain of the DeMOS transistor 116. The respective sources of the DeMOS transistors 116 and 118 are coupled to the bias circuit 106. The cross-coupled pair circuit 104 may also include AC coupling capacitors 120 and 122. The capacitor 120 may be connected between the gate of the DeMOS transistor 118 and the drain of the DeMOS transistor 116. The capacitor 122 may be connected between the gate of the DeMOS transistor 116 and the drain of the DeMOS transistor 118. Further discussion of the DeMOS transistors 116 and 118 and the AC coupling capacitors 120 and 122 is given in the following.

The bias circuit 106 may be implemented using various circuit topologies. In one implementation, the bias circuit 106 is a current mirror circuit that uses PMOS or NMOS transistors. In another implementation, the bias circuit 106 is simply a short circuit to ground. Other known biasing circuits may also be used to realize the bias circuit 106.

Prior to the use of DeMOS devices in a VCO, which is first described herein, DeMOS devices were often employed for applications such as power switching circuits. DeMOS devices employ a drain extension region which substantially increases operating voltages of the devices. DeMOS devices advantageously combine short-channel operation with high current handling capabilities, relatively low drain-to-source on-state resistance, and the ability to withstand relatively high drain-to-source voltages without suffering voltage breakdown failure. In addition to performance advantages, DeMOS device fabrication is relatively easy to integrate into CMOS process flows, facilitating use in devices where logic, low power analog, or other circuitry is also to be fabricated in a single integrated circuit (IC).

The high drain-to-source voltages of DeMOS devices may result in relatively high gate-to-source voltages. However, integrated circuit processing requirements often necessitate having a low gate-to-source voltages (e.g., <1.2 volts in 65 nm CMOS). Therefore, in one implementation, the VCO 100 uses the AC coupling capacitors 120 and 122 to respectively control the volt level at the gates of the DeMOS transistors 116 and 118. In particular, the AC coupling capacitors 120 and 122 help to prevent a high voltage that may be present on the respective drains of the DeMOS transistors 116 and 118 from affecting the respective gates of the transistors 116 and 118.

Unlike conventional VCO circuit arrangements, which have the same voltage swing on the gate and drain of the active devices, the VCO implementations described herein allow for a greater voltage swing on the drain as compared to the voltage swing on the gate. This is achieved through the use of the DeMOS transistors 116 and 118. The greater voltage swing on the drain significantly improves phase noise characteristics.

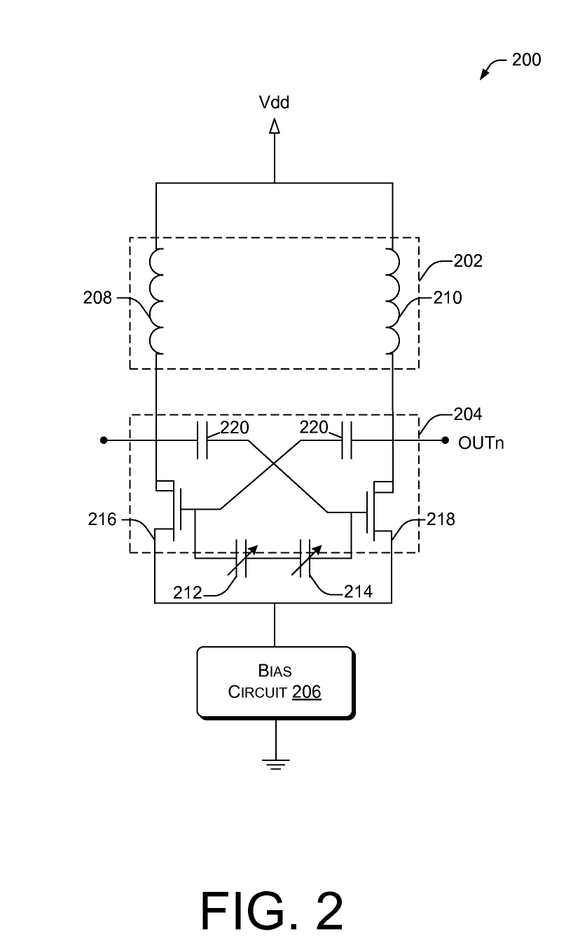

FIG. 2 is a diagram of a VCO 200 according to a second circuit arrangement implementation. The VCO 200 includes, but is not limited to, an LC-tank circuit 202, a cross-coupled pair circuit 204, and bias circuit 206.

The LC-tank circuit 202 is coupled to Vdd. The LC-tank circuit 202 includes inductors 208 and 210 and varactors 212 and 214, which are respectively used for providing an inductance and a capacitance to generate a differential oscillating signal between output terminals OUTn and OUTp. Unlike in VCO 100, the switchable varactors 212 and 214 are coupled to the gates of cross-coupled drain extended MOS transistors (DeMOS) 216 and 218, respectively, instead of the drains as shown in FIG. 1. The inductors 208 and 210 are coupled to Vdd in parallel. The varactors 212 and 214 may be implemented using diodes or MOS capacitances. This is achieved by replacing the illustrated varactors 212 and 214 with junction diodes, or any MOS transistor used as a variable capacitance by short-circuiting the drain and source.

The cross-coupled pair circuit 204 includes cross-coupled drain extended MOS transistors (DeMOS) 216 and 218. The DeMOS transistors 216 and 218 are cross-coupled such that the gate of the DeMOS transistor 216 is coupled to the drain of the DeMOS transistor 218, and the gate of the DeMOS transistor 218 is coupled to the drain of the DeMOS transistor 216. The respective sources of the DeMOS transistors 216 and 218 are coupled to the bias circuit 206. The cross-coupled pair circuit 204 may also include AC coupling capacitors 220 and 222. The capacitor 220 may be connected between the gate of the DeMOS transistor 218 and the drain of the DeMOS transistor 216. The capacitor 222 may be connected between the gate of the DeMOS transistor 216 and the drain of the DeMOS transistor 218. Further discussion of the DeMOS transistors 216 and 218 and the AC coupling capacitors 220 and 222 is given in the following.

The bias circuit 206 may be implemented using various circuit topologies. In one implementation, the bias circuit 206 is a current mirror circuit that uses PMOS or NMOS transistors. In another implementation, the bias circuit 206 is simply a short circuit to ground. Other known biasing circuits may also be used to realize the bias circuit 206.

Prior to the use of DeMOS devices in a VCO, which is first described herein, DeMOS devices were often employed for applications such as power switching circuits. DeMOS devices employ a drain extension region which substantially increases operating voltages of the devices. DeMOS devices advantageously combine short-channel operation with high current handling capabilities, relatively low drain-to-source on-state resistance, and the ability to withstand relatively high drain-to-source voltages without suffering voltage breakdown failure. In addition to performance advantages, DeMOS device fabrication is relatively easy to integrate into CMOS process flows, facilitating use in devices where logic, low power analog, or other circuitry is also to be fabricated in a single integrated circuit (IC).

The high drain-to-source voltages of DeMOS devices may result in relatively high gate-to-source voltages. However, integrated circuit processing requirements often necessitate having a low gate-to-source voltages (e.g., <1.2 volts). Therefore, in one implementation, the VCO 200 uses the AC coupling capacitors 220 and 222 to respectively control the volt level at the gates of the DeMOS transistors 216 and 218. In particular, the AC coupling capacitors 220 and 222 help to prevent a high voltage that may be present on the respective drains of the DeMOS transistors 216 and 218 from affecting the respective gates of the transistors 216 and 218.

Unlike conventional VCO circuit arrangements, which have the same voltage swing on the gate and drain of the active devices, the VCO implementations described herein allow for a greater voltage swing on the drain as compared to the voltage swing on the gate. This is achieved through the use of the DeMOS transistors 216 and 218. The greater voltage swing on the drain significantly improves phase noise.

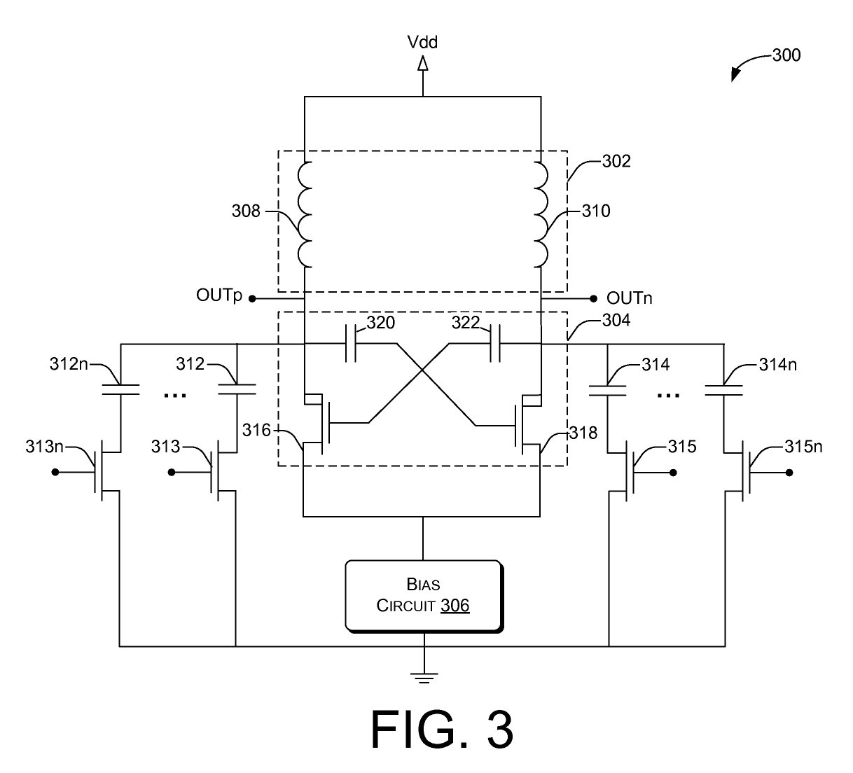

FIG. 3 is a diagram of a digitally controlled oscillator (DCO) 300 according to a third circuit arrangement implementation. The DCO 300 includes, but is not limited to, an LC-tank circuit 302, a cross-coupled pair circuit 304, and bias circuit 306.

The LC-tank circuit 302 is coupled to Vdd. The LC-tank circuit 302 includes inductors 308 and 310 and digital varactors 312 and 314, which are respectively used for providing an inductance and a capacitance to generate a differential oscillating signal between output terminals OUTn and OUTp. A plurality of digital varactors (312n and 314n) may be provided to achieve a desired tuning of the LC-tank circuit 302. Active devices 313 . . . 313n and 315 . . . 315n are provided to control the behavior of respective ones of the digital varactors 312 and 314. The inductors 308 and 310 are coupled to Vdd in parallel.

The cross-coupled pair circuit 304 includes cross-coupled drain extended MOS transistors (DeMOS) 316 and 318. The DeMOS transistors 316 and 318 are cross-coupled such that the gate of the DeMOS transistor 316 is coupled to the drain of the DeMOS transistor 318, and the gate of the DeMOS transistor 318 is coupled to the drain of the DeMOS transistor 316. The respective sources of the DeMOS transistors 316 and 318 are coupled to the bias circuit 306. The cross-coupled pair circuit 304 may also include AC coupling capacitors 320 and 322. The capacitor 320 may be connected between the gate of the DeMOS transistor 318 and the drain of the DeMOS transistor 316. The capacitor 322 may be connected between the gate of the DeMOS transistor 316 and the drain of the DeMOS transistor 318. Further discussion of the DeMOS transistors 316 and 318 and the AC coupling capacitors 320 and 322 is given in the following. To further enhance the operation of the DCO 300, the active devices 313 . . . 313n and 315 . . . 315n may also be replaced with DeMOS transistors.

The bias circuit 306 may be implemented using various circuit topologies. In one implementation, the bias circuit 306 is a current mirror circuit that uses PMOS or NMOS transistors. In another implementation, the bias circuit 306 is simply a short circuit to ground. Other known biasing circuits may also be used to realize the bias circuit 306.

Prior to the use of DeMOS devices in a DCO, which is first described herein, DeMOS devices were often employed for applications such as power switching circuits. DeMOS devices employ a drain extension region which substantially increases operating voltages of the devices. DeMOS devices advantageously combine short-channel operation with high current handling capabilities, relatively low drain-to-source on-state resistance, and the ability to withstand relatively high drain-to-source voltages without suffering voltage breakdown failure. In addition to performance advantages, DeMOS device fabrication is relatively easy to integrate into CMOS process flows, facilitating use in devices where logic, low power analog, or other circuitry is also to be fabricated in a single integrated circuit (IC).

The high drain-to-source voltages of DeMOS devices may result in relatively high gate-to-source voltages. However, integrated circuit processing requirements often necessitate having a low gate-to-source voltages (e.g., <1.2 volts). Therefore, in one implementation, the VCO 300 uses the AC coupling capacitors 320 and 322 to respectively control the volt level at the gates of the DeMOS transistors 316 and 318. In particular, the AC coupling capacitors 320 and 322 help to prevent a high voltage that may be present on the respective drains of the DeMOS transistors 316 and 318 from affecting the respective gates of the transistors 316 and 318.

Unlike conventional DCO circuit arrangements, which have the same voltage swing on the gate and drain of the active devices, the DCO implementations described herein allow for a greater voltage swing on the drain as compared to the voltage swing on the gate. This is achieved through the use of the DeMOS transistors 316 and 318. The greater voltage swing on the drain significantly improves phase noise.

The implementations described herein show VCO and DCO circuit arrangements the make use of cross coupled DeMOS transistors (differential arrangement). However, the implementations are not limited to the described and illustrated differential arrangements. In particular, DeMOS transistors may also be used VCO and DCO circuit arrangements that use one active device (single-ended arrangements). For example, in one implementation, a single-ended VCO implements a DeMOS transistor. In another implementation, a single-ended DCO implements a DeMOS transistor.

For the purposes of this disclosure and the claims that follow, the terms “coupled” and “connected” have been used to describe how various elements interface. Such described interfacing of various elements may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims. The specific features and acts described in this disclosure and variations of these specific features and acts may be implemented separately or may be combined.

1. A circuit arrangement, comprising:
a voltage controlled oscillator (VCO) circuit having at least one active device, wherein the at least one active device is a drain extended (DeMOS) MOS transistors.

2. The arrangement of claim 1, wherein the at least one active device is DeMOS devices that are cross-coupled.

3. The arrangement of claim 2, wherein gates of the DeMOS devices are cross-coupled.

4. The arrangement of claim 2, wherein the VCO circuit further includes an LC tank coupled to the DeMOS transistors.

5. The arrangement of claim 4, wherein the LC tank includes at least an inductor and a varactor.

6. The arrangement of claim 4, wherein the LC tank includes at least two inductors and two varactors.

7. The arrangement of claim 2, wherein in each gate associated with the DeMOS transistors has an AC coupling capacitor coupled thereto.

8. The arrangement of claim 1, further comprising a bias circuit coupled to the VCO circuit.

9. A voltage controlled oscillator (VCO) circuit, comprising:
an LC tank;
cross-coupled drain extended MOS (DeMOS) transistors coupled to the LC tank; and
a bias circuit coupled to the DeMOS transistors.

10. The VCO circuit of claim 9, wherein the LC tank comprises two inductors and two varactors.

11. The VCO circuit of claim 9, further comprising an AC capacitor coupled to each of the DeMOS transistors.

12. The VCO circuit of claim 11, wherein a first AC capacitor is coupled to a gate of a first DeMOS transistor and a second AC capacitor is coupled to a gate of a second DeMOS transistor.
